(19) United States
(12) Patent Application Publication
(10) Pub. No.: US 2017/0099190 A1
(43) Pub. Date: Apr. 6, 2017

(54) DATA CENTER RACK FLEXPLANE

(71) Applicant: Seagate Technology LLC, Cupertino, CA (US)

(72) Inventors: Richard Charles Alexander Pitwon, Fareham (GB); Alexander Carl Worrall, Waterlooville (GB); Alistair Allen Miller, Hayling Island (GB)

(21) Appl. No.: 14/874,118

(22) Filed: Oct. 2, 2015

(51) Int. Cl. H04L 12/24

(52) U.S. Cl. CPC H04L 41/12

(57) ABSTRACT

The disclosed technology provides a system comprising a data center rack including one or more enclosures, each of the enclosures including one or more devices, and a plurality of flexplane units configured to interconnect with each other so as to interconnect a plurality of nodes in a torus topology, the one or more of the plurality of nodes is connected to one or more of the devices.

### SUMMARY

Certain embodiments of the present disclosure include a system comprising a data center rack including one or more enclosures, each of the enclosures including one or more devices, and a plurality of flexplane units configured to interconnect with each other so as to interconnect a plurality of nodes in a torus topology, the one or more of the plurality of nodes is connected to one or more of the devices.

This Summary is provided to introduce a selection of concepts in a simplified form that are further described below in the Detailed Descriptions. This Summary is not intended to identify key features or essential features of the claimed subject matter, nor is it intended to be used to limit the scope of the claimed subject matter. Other features, details, utilities, and advantages of the claimed subject matter will be apparent from the following more particular written Detailed Descriptions of various implementations as further illustrated in the accompanying drawings and defined in the appended claims.

These and various other features and advantages will be apparent from a reading of the following Detailed Descriptions.

### BRIEF DESCRIPTIONS OF THE DRAWINGS

FIG. 1 illustrates a perspective view of an example data center rack system implementing a torus topology.

FIG. 2 illustrates an isometric side view of an example data center rack system comprising interconnected flexplanes implementing a torus topology.

FIG. 3 illustrates an isometric side view of an example data center rack system comprising interconnected flexplanes implementing a torus topology.

FIG. 4 illustrates an isometric side view of an example data center rack system comprising interconnected flexplanes implementing a torus topology.

FIG. 5 illustrates an isometric side view of an example data center rack system comprising interconnected flexplanes implementing a torus topology.

FIG. 6 illustrates an isometric side view of an example data center rack system comprising interconnected flexplanes implementing a torus topology.

FIG. 7 illustrates an isometric side view of an example data center rack system comprising interconnected flexplanes implementing a torus topology.

### DETAILED DESCRIPTIONS

Torus interconnect topologies are network architectures for connecting network nodes or servers in mesh-like formation in computer systems. In such topologies, server nodes are directly connected together in multi-dimensional (e.g., 3D, 4D, 5D, 6D, . . . nD) arrangements, which determine the level of interconnectivity. These multi-dimensional topologies can be depicted as n dimensional arrays connecting servers to other nodes or servers.

For each one-dimensional or 1D torus, two nodes are interconnected. For a two-dimensional (2D) torus, 4 nodes are interconnected. For a three-dimensional (3D) torus, 6 nodes are interconnected. For a four-dimensional (4D) torus, 8 nodes are interconnected. For a five-dimensional (5D) torus, 10 nodes are interconnected. For a six-dimensional (6D) torus, 12 nodes are interconnected and so on. In general, for an n-dimensional torus, 2n nodes are interconnected. Switchless torus interconnect topologies can provide linear scalability and substantial reduction in cost and power for exascale data centers.

Each node provides access to any node or server with a minimum number of “hops” (i.e., intermediary nodes that a communication signal must pass through from an originator node to a target node). The higher the number of dimensions, the lower the number of hops a communication signal will need to make between an originator node and a target node and therefore the lower the network latency. As the dimensionality increases or scales in a torus architecture, the number of interconnect ports on each node must scale two-fold (i.e., in an n dimensional torus architecture, node port count=2n). For example, server nodes in a 2D torus architecture require 4 ports, nodes in a 3D architecture require 6 ports, nodes in a 4D architecture require 8 ports, etc. In further embodiments, server nodes in a 5D torus architecture require 10 ports, and nodes in a 6D architecture require 12 ports.

The disclosed technology provides a data center rack, a torus architecture, and interconnectable flexplanes (in some embodiments, optical flexplanes) configured to connect the data center rack and the torus architecture for various computing equipment. The flexplanes can be modular to implement intra- and inter-dimensionally scalable torus technology. The number of dimensions of the torus topology can vary (e.g., 2D, 3D, 4D, 5D, 6D, etc.).

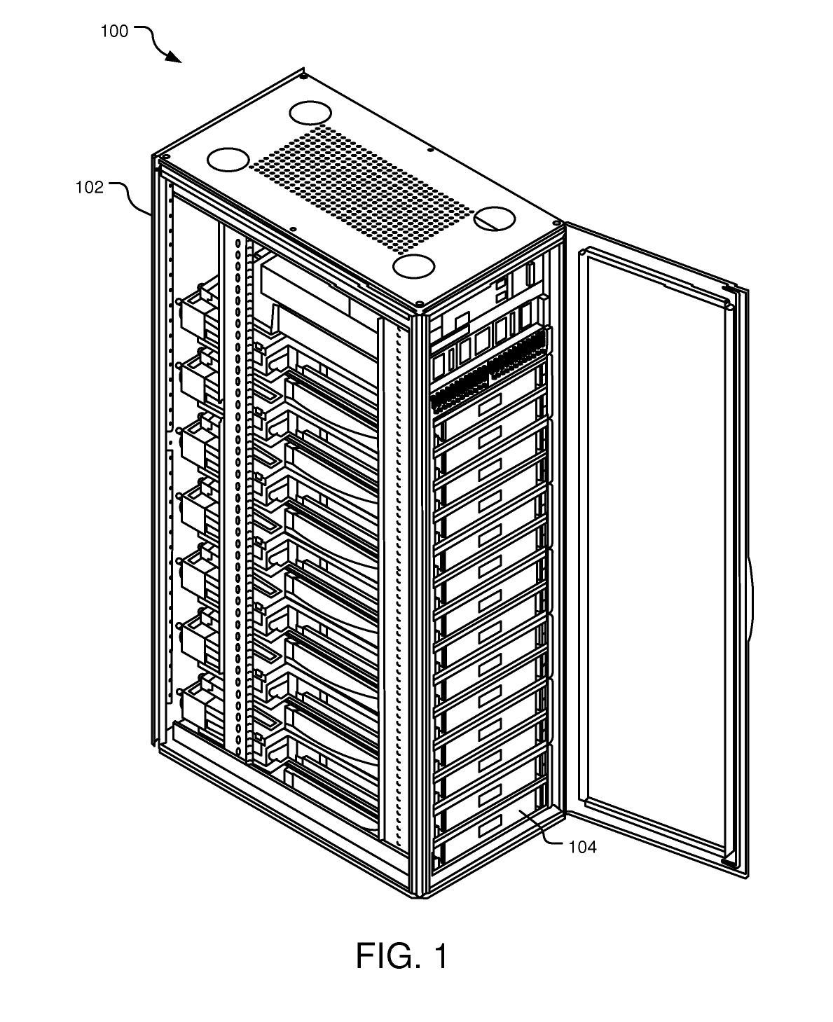

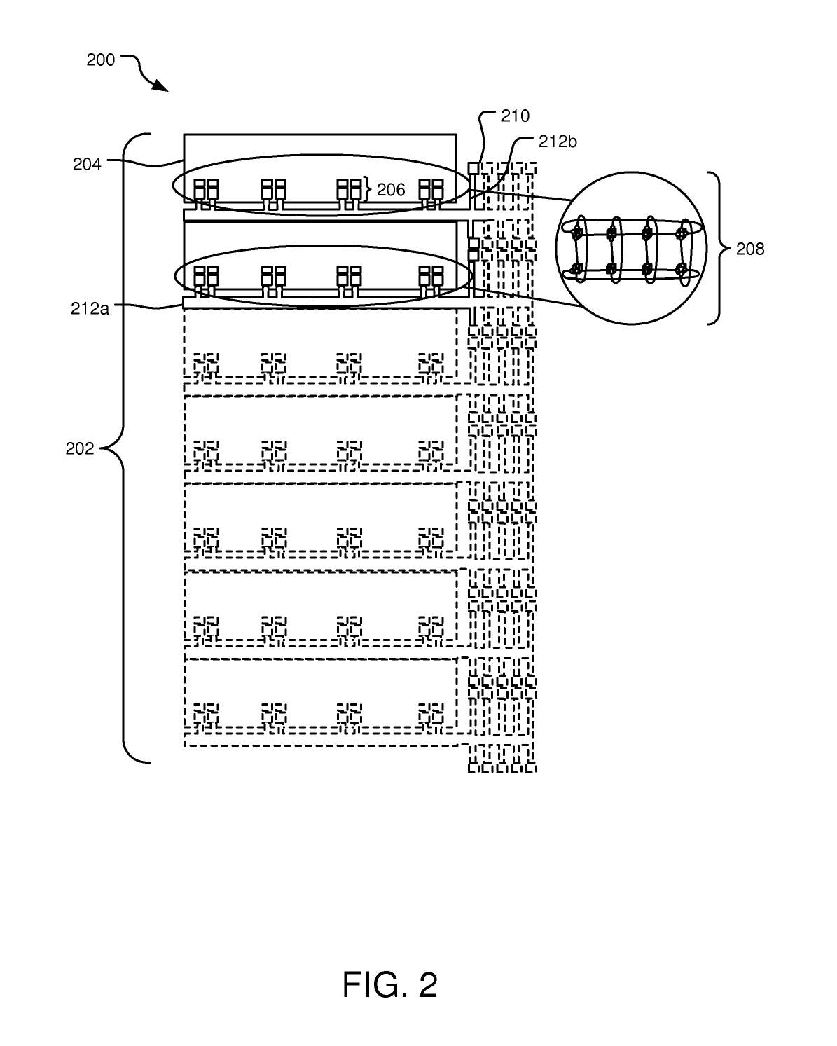

FIG. 1 illustrates a perspective view of an example data center rack system 100 implementing a torus topology. A rack 102 is shown with 14 servers or storage enclosures 104. A number of flexplanes or flexplane units with an nD torus topology is implemented within the enclosures 104 (shown and described in detail in FIGS. 2-7). Flexplanes or flexplane units may comprise a variety of configurations and components. In one implementation, a flexplane may be an electrical data connection cable or flexible optical cable with a user-defined mapping. Flexplanes can be implemented as individual interconnects, fibers or fiber groups attached in a user-defined way to a set of terminating connectors. In another implementation, a flexplane can be a basic fiber cable with at least one fiber terminated on both ends by a connector. In some implementations, a flexplane can comprise a complex mapping of optical fibers laminated within a flexible substrate with at least two connector terminations. In yet another implementation, a flexplane may comprise polymer waveguides fabricated on a flexible substrate terminated with connectors. The enclosures 104 may each include one or more devices (e.g., end device, server, microserver, computer, data storage device etc.).

Due to the modular nature of the flexplanes, the number and location of flexplanes implemented in a data system rack system can vary. A modular optical horizontal flexplane can be located extending horizontally in an enclosure 104 connecting to nodes at ports (not shown) in the enclosure 104. The modular optical horizontal flexplane can be located near the bottom of an enclosure 104, or other locations are contemplated. A modular optical vertical flexplane can extend vertically connected to a rack 102 via horizontally extending flexplanes and to extension points. The extension points connect a vertical flexplane to another vertical flexplane. In some implementations, a vertical flexplane can optically interconnect devices located within two enclosures located at different vertical levels. In some implementations, a horizontal flexplane can optically interconnect devices located within one enclosure. In some implementations, a vertical flexplane can optically interconnect with at least one horizontal flexplane. Various configurations of the vertical and horizontal flexplanes can be implemented to provide the intra- and inter-dimensionally scalable torus technology. Such various configurations also provide access to nodes that are located in numerous locations throughout the rack and may not be conveniently reached for connections (e.g., nodes located away from the edges of the enclosures).

For example, there can be more than one vertical flexplane per enclosure. A vertical flexplane can span two or more enclosures to limit the number of connection points. Each connection point has a loss associated with it (e.g., 0.5 dB). It may be advantageous to minimize the number of connection points. In one implementation, one or more vertical flexplanes can span an entire rack. The greater number of vertical flexplanes spanning a rack provides more fabrication capabilities, and thus, less overall cost. In some implementations, each vertical flexplane spans two, three, or four enclosures. Different types of flexplanes can be used to accommodate different numbers of enclosures in a rack with minimum interconnection (e.g., a rack with eight enclosures can have two large vertical flexplanes (each flexplane spanning four enclosures). In another implementation, a rack comprising seven enclosures may have one large vertical flexpane (spanning four enclosures) and one medium flexplane (spanning three enclosures).

A flexplane section connecting to a given node can be designed depending on a desired interdimensional scalability (how many dimensions to scale a particular inter-node torus interconnect). For example, at each node connection point, an optical connector (e.g., a MT parallel optical ferrule) can have up to 64 fibers, accommodate 32 ports (bidirectional links), and accommodate a maximum 16-dimensional torus. For example, 32 fibers in a MT ferrule can be populated to allow 16 ports equating to a maximum torus dimensionality of eight (or 8D torus). If only a 2D torus is required, an 8D overprovisioned flexplane segment in the horizontal plane can still be populated. In the vertical plane, however, only the fibers in the vertical flexplanes that interconnect different enclosures to implement a 2D torus would be utilized.

As node port capacities increase over time, as a data center increases in scale, nodes can be interchanged with new nodes with higher port counts. For example, there is capacity to scale up to a 3D torus by using a different vertical flexplane. Vertical flexplanes can be replaced with new vertical flexplanes until the horizontal segments reach a maximum capacity. As a data center bandwidth scales, only vertical segments need to be replaced rather than an entire local flexplane infrastructure.

In other implementations, where fiber cables and flexplane technology within a rack are required to provide interconnectivity between server nodes, the use of cables attached between each node and an optical patch-panel can become prohibitively expensive and difficult to scale. Particularly, as node density increases, space taken up by the discrete cables becomes an impediment to access to the front fascia of rack enclosures.

The modular interconnectable flexplanes based on embedded fiber optic links disclosed herein incorporate very high densities of optical links and support high torus dimensionalities. Even if the maximum dimension of interconnect is not used at one time, there is potential for future accommodation by connecting additional flexplanes to an access point(s). As a result, the disclosed system provides efficient optical channel and scalable connector interface densities. For example, by using parallel optical connector technologies to interface to each node, (e.g., MXC connectors incorporating MT ferrules), each node can support up to 32 bidirectional ports (64 optical links), and a maximum torus interconnect dimension of 16D, assuming one MXC connection per node. In another implementation, each node can support more than 32 bidirectional ports using multiple MT type optical connectors.

FIG. 2 illustrates a perspective view of an example data center rack system 200 comprising enclosures 204 and interconnected flexplanes 212 (e.g., a horizontal flexplane 212a, a vertical flexplane 212b) implementing a torus topology. A rack 202 is shown with capacity for seven servers or storage enclosures 204. A 2D interconnect topology 208 with two enclosures is populated.

Due to the modular nature of the flexplanes 212, the number and location of flexplanes 212 implemented in a data system rack 202 can vary. A modular optical horizontal flexplane 212a can be located extending horizontally near the bottom of an enclosure 204 connecting to nodes at ports 206 in the enclosure 204, as shown in FIG. 2. A modular optical vertical flexplane 212b can extend vertically connected to a rack 202 via horizontally extending flexplanes (e.g., flexplane 212a) and to extension points (e.g., extension point 210). The extension points 210 connect a vertical flexplane 212b to another vertical flexplane 212b. In some implementations, a vertical flexplane 212b can optically interconnect devices located within two enclosures 204 located at different vertical levels. In some implementations, a horizontal flexplane 212a can optically interconnect devices located within one enclosure 204. In some implementations, a vertical flexplane 212b can optically interconnect with at least one horizontal flexplane 212a. Various configurations of the vertical and horizontal flexplanes 212 can be implemented to provide the intra- and inter-dimensionally scalable torus technology. Such various configurations also provide access to nodes that are located in numerous locations throughout the rack and may not be conveniently reached for connections (e.g., nodes located away from the edges of the enclosures).

Referring to FIG. 2, two modular optical flexplanes 212 are located extending horizontally near the bottom of the two enclosures 204 connecting to nodes at ports 206 in the enclosures 204. Two modular optical flexplanes 212 are located extending vertically connected to the rack 202 via the horizontally extending flexplanes 212 and to extension points 210. An exploded view shows the torus topology 208 in this implementation. Two 1D (1×4) tori are connected together to form a 2D (2×4) torus.

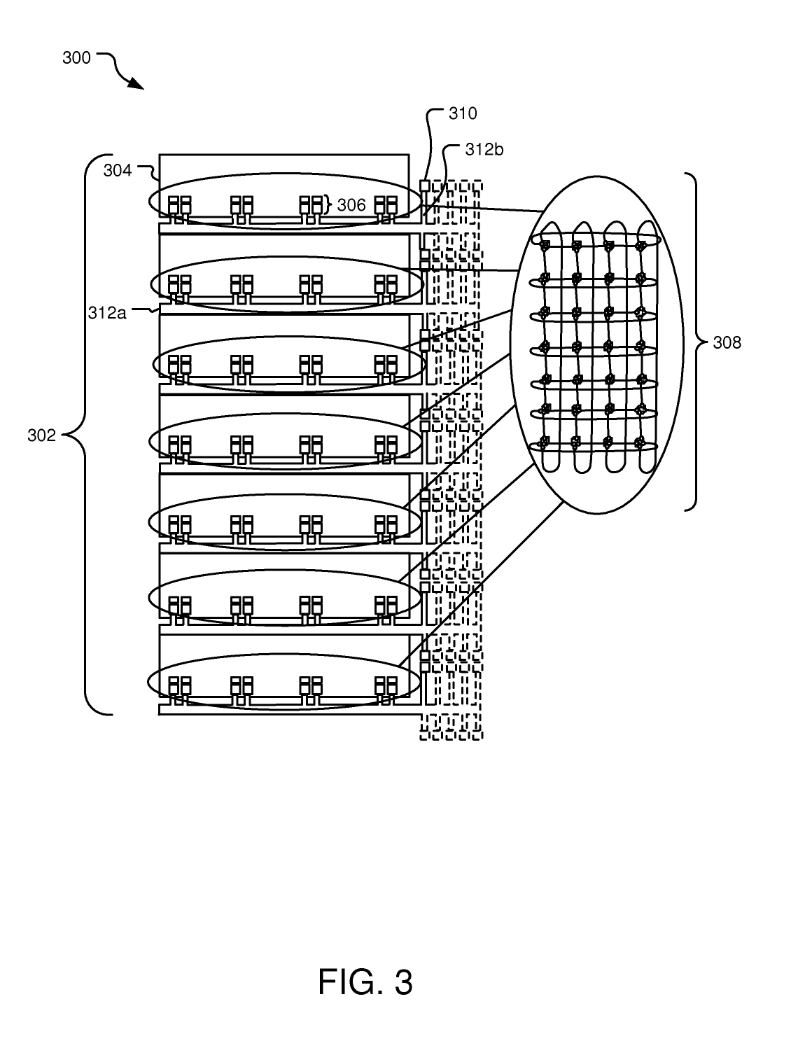

FIG. 3 illustrates an isometric side view of an example data center rack system 300 comprising interconnected flexplanes 312 implementing a torus topology. A rack 302 is shown with seven servers or storage enclosures 304 and a 2D interconnect topology 308.

Due to the modular nature of the flexplanes 312, the number and location of flexplanes 312 (e.g., flexplane 312a, flexplane 312b) implemented in a data system rack 302 can vary. A modular optical horizontal flexplane 312a can be located extending horizontally near the bottom of an enclosure 304 connecting to nodes at ports (e.g., port 306) in the enclosure 304, as shown in FIG. 3. A modular optical vertical flexplane 312b can extend vertically connected to a rack 302 via horizontally extending flexplanes (e.g., flexplane 312a) and to extension points (e.g., extension point 310). The extension points 310 connect a vertical flexplane 312b to another vertical flexplane 312b. In some implementations, a vertical flexplane 312b can optically interconnect devices located within two enclosures 304 located at different vertical levels. In some implementations, a horizontal flexplane 312a can optically interconnect devices located within one enclosure 304. In some implementations, a vertical flexplane 312b can optically interconnect with at least one horizontal flexplane 312a. Various configurations of the vertical and horizontal flexplanes 312 can be implemented to provide the intra- and inter-dimensionally scalable torus technology. Such various configurations also provide access to nodes that are located in numerous locations throughout the rack and may not be conveniently reached for connections (e.g., nodes located away from the edges of the enclosures).

Seven modular optical flexplanes 312 are located extending horizontally near the bottom of the seven enclosures 304 connecting to nodes at ports 306 in the enclosures 304. Seven modular optical flexplanes 312 are located extending vertically connected to the rack 302 via the horizontally extending flexplanes 312 and to extension points 310. An exploded view shows the torus topology 308 in this implementation. Seven 1D (1×4) tori are connected together to form a 2D (7×4) torus.

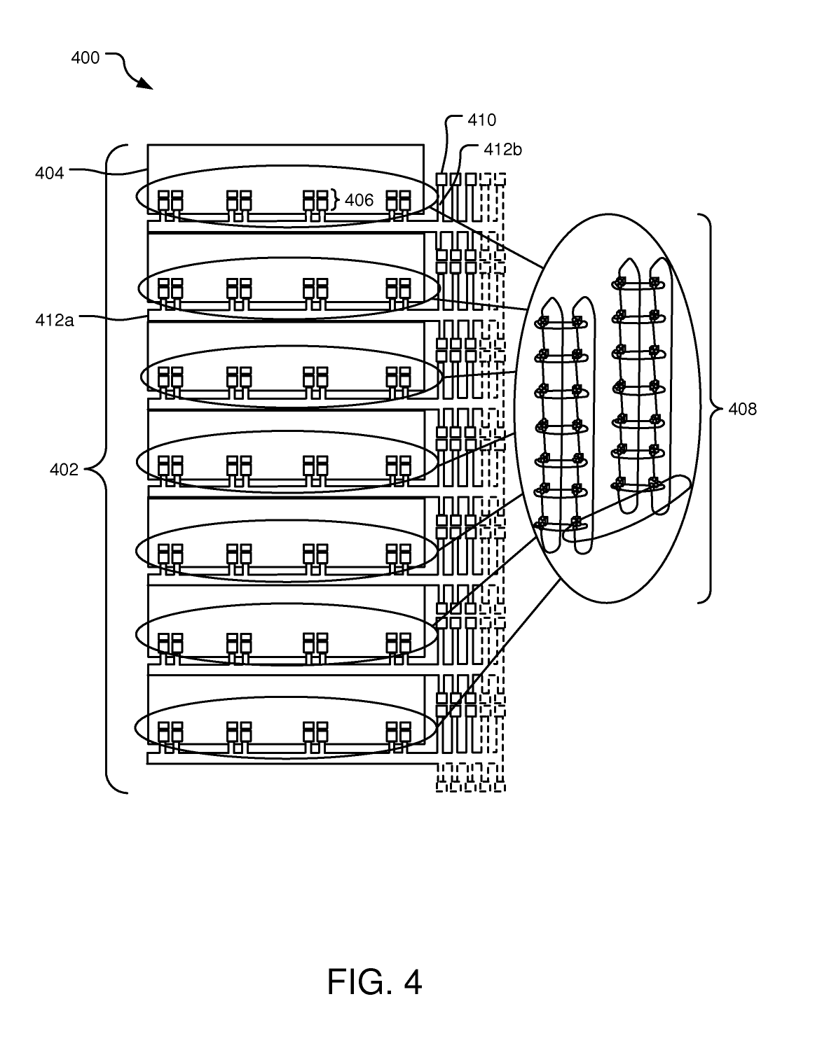

FIG. 4 illustrates an isometric side view of an example data center rack system 400 comprising interconnected flexplanes 412 (e.g., flexplane 412a, flexplane 412b) implementing a nD torus topology. A rack 402 is shown with seven servers or storage enclosures 404 and a 3D interconnect (2×7×2) torus topology 408.

Due to the modular nature of the flexplanes 412, the number and location of flexplanes 412 (e.g., flexplane 412a, flexplane 412b) implemented in a data system rack 402 can vary. A modular optical horizontal flexplane 412a can be located extending horizontally near the bottom of an enclosure 404 connecting to nodes at ports (e.g., port 406) in the enclosure 404, as shown in FIG. 4. A modular optical vertical flexplane 412b can extend vertically connected to a rack 402 via horizontally extending flexplanes (e.g., flexplane 412a) and to extension points (e.g., extension point 410). The extension points 410 connect a vertical flexplane 412b to another vertical flexplane 412b. In some implementations, a vertical flexplane 412b can optically interconnect devices located within two enclosures 404 located at different vertical levels. In some implementations, a horizontal flexplane 412a can optically interconnect devices located within one enclosure 404. In some implementations, a vertical flexplane 412b can optically interconnect with at least one horizontal flexplane 412a. Various configurations of the vertical and horizontal flexplanes 412 can be implemented to provide the intra- and inter-dimensionally scalable torus technology. Such various configurations also provide access to nodes that are located in numerous locations throughout the rack and may not be conveniently reached for connections (e.g., nodes located away from the edges of the enclosures).

Referring to FIG. 4, seven modular optical flexplanes 412 are located extending horizontally near the bottom of the seven enclosures 404 connecting to nodes at ports 406 in the enclosures 404. Seven modular optical flexplanes 412 are located extending vertically connected to the rack 402 via the horizontally extending flexplanes 412 and to extension points 410. An exploded view shows the torus topology 408 in this implementation. Two 2D (7×2) tori are connected together to form a 3D (2×7×2) torus.

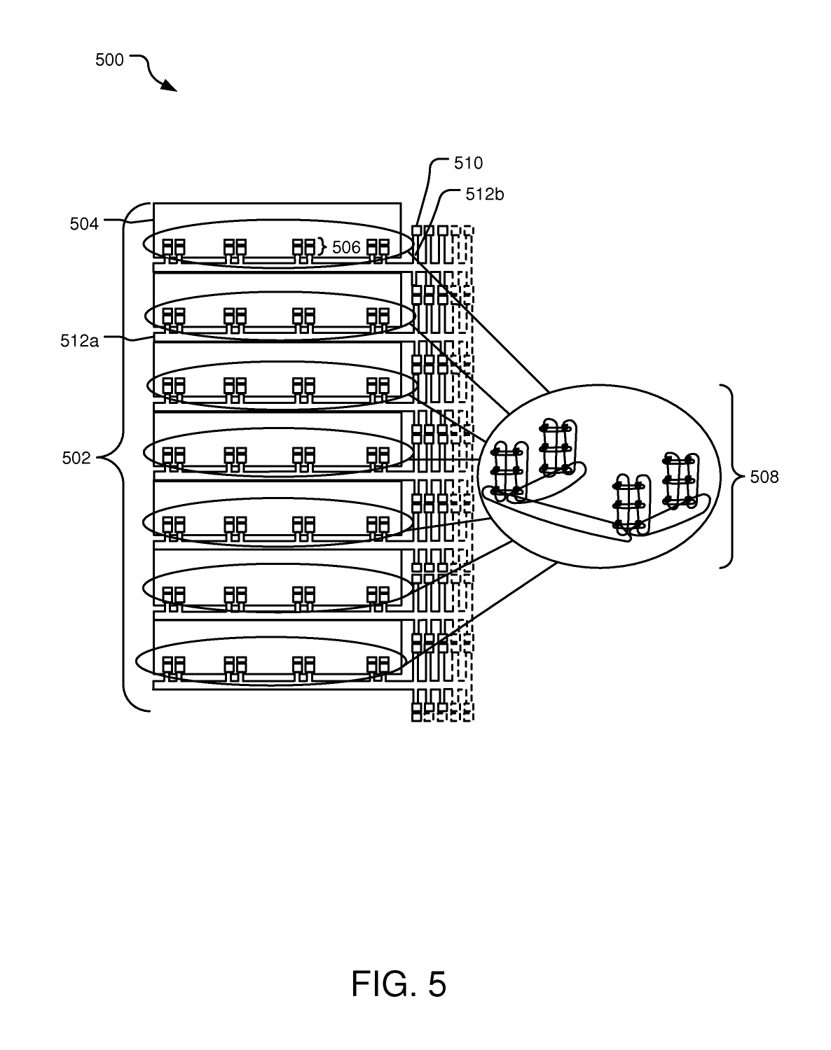

FIG. 5 illustrates an isometric side view of an example data center rack system 500 comprising interconnected flexplanes 512 (e.g., flexplane 512a, flexplane 512b) implementing nD torus topology. A rack 502 is shown with six servers or storage enclosures 504 and a 4D interconnect topology 508. Similar related rack topologies can be utilized to extend from a 4D interconnect topology to a 5D and 6D topology.

Due to the modular nature of the flexplanes 512, the number and location of flexplanes 512 (e.g., flexplane 512a, flexplane 512b) implemented in a data system rack 502 can vary. A modular optical horizontal flexplane 512a can be located extending horizontally near the bottom of an enclosure 504 connecting to nodes at ports (e.g., port 506) in the enclosure 504, as shown in FIG. 5. A modular optical vertical flexplane 512b can extend vertically connected to a rack 502 via horizontally extending flexplanes (e.g., flexplane 512a) and to extension points (e.g., extension point 510). The extension points 510 connect a vertical flexplane 512b to another vertical flexplane 512b. In some implementations, a vertical flexplane 512b can optically interconnect devices located within at least two enclosures 504 located at different vertical levels. In some implementations, a horizontal flexplane 512a can optically interconnect devices located within one enclosure 504. In some implementations, a vertical flexplane 512b can optically interconnect with at least one horizontal flexplane 512a. Various configurations of the vertical and horizontal flexplanes 512 can be implemented to provide the intra- and inter-dimensionally scalable torus technology. Such various configurations also provide access to nodes that are located in numerous locations throughout the rack and may not be conveniently reached for connections (e.g., nodes located away from the edges of the enclosures).

Referring to FIG. 5, seven modular optical flexplanes 512 are located extending horizontally near the bottom of the seven enclosures 504 connecting to nodes at ports 506 in the enclosures 504. Seven modular optical flexplanes 512 are located extending vertically connected to the rack 502 via the horizontally extending flexplanes 512 and to extension points 510. An exploded view shows the torus topology 508 in this implementation. Two 3D (3×2) tori are connected together to form a 4D (3×2×2×2) torus. In this implementation, the limits of dimensionality have been reached for a single rack. It is not possible to increase the torus dimensionality any further without increasing the number of nodes.

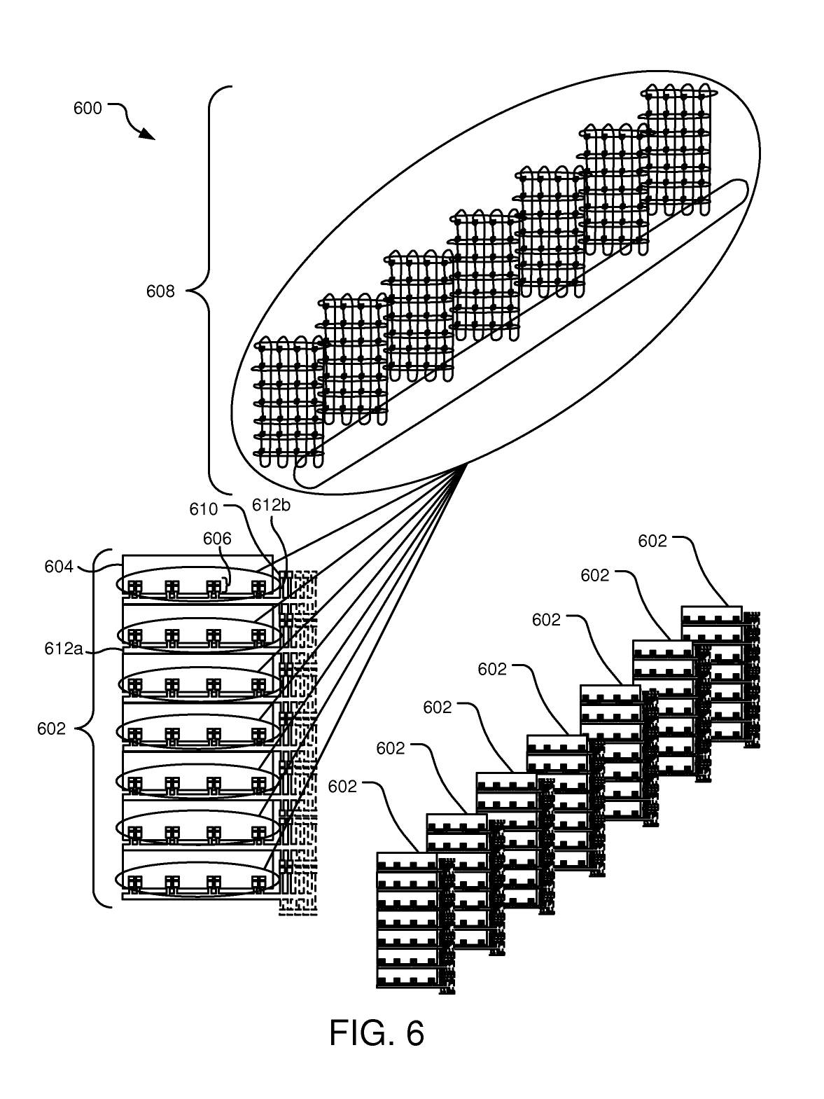

FIG. 6 illustrates an isometric side view of an example data center rack system 600 comprising interconnected flexplanes 612 (e.g., flexplane 612a, flexplane 612b) implementing nD torus topology 608. In addition to the number of flexplanes, enclosures, and devices, the number of racks can also vary in the disclosed technology. FIG. 6 also shows seven racks 602, with seven servers or storage enclosures 604 in each rack and a 3D interconnect topology 608.

Due to the modular nature of the flexplanes 612, the number and location of flexplanes 612 (e.g., flexplane 612a, flexplane 612b) implemented in a data system rack 602 can vary. A modular optical horizontal flexplane 612a can be located extending horizontally near the bottom of an enclosure 604 connecting to nodes at ports (e.g., port 606) in the enclosure 604, as shown in FIG. 6. A modular optical vertical flexplane 612b can extend vertically connected to a rack 602 via horizontally extending flexplanes (e.g., flexplane 612a) and to extension points (e.g., extension point 610). The extension points 610 connect a vertical flexplane 612b to another vertical flexplane 612b. In some implementations, a vertical flexplane 612b can optically interconnect devices located within two enclosures 604 located at different vertical levels. In some implementations, a horizontal flexplane 612a can optically interconnect devices located within one enclosure 604. In some implementations, a vertical flexplane 612b can optically interconnect with at least one horizontal flexplane 612a. Various configurations of the vertical and horizontal flexplanes 612 can be implemented to provide the intra- and inter-dimensionally scalable torus technology. Such various configurations also provide access to nodes that are located in numerous locations throughout the rack and may not be conveniently reached for connections (e.g., nodes located away from the edges of the enclosures).

Referring to FIG. 6, forty-nine modular optical flexplanes 612 are located extending horizontally near the bottom of the six enclosures 604 connecting to nodes at ports 606 in the enclosures 604. Forty-nine modular optical flexplanes 612 are located extending vertically connected to the rack 602 via the flexplanes 612 extending horizontally and to extension points 610. An exploded view shows the torus topology 608 in this implementation. Seven 2D (7×4) tori are connected together to form a 3D (7×4×7) torus. In this implementation, the links between the bottom right hand node from 2D plane to 2D plane is shown.

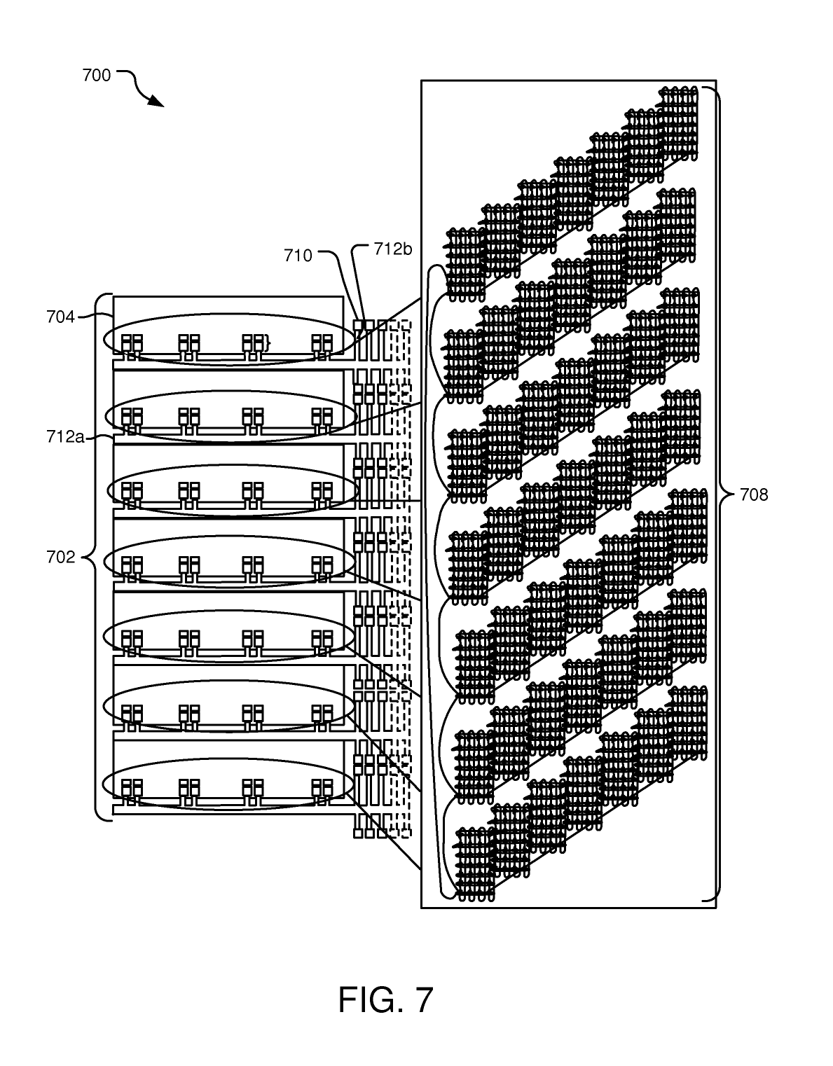

FIG. 7 illustrates an isometric side view of an example data center rack system 700 comprising interconnected flexplanes 712 (e.g., flexplane 712a, flexplane 712b) implementing nD torus topology 708. Sevens racks are shown with seven servers or storage enclosures 704 in each rack 702 and a 4D interconnect topology 708.

Due to the modular nature of the flexplanes 712, the number and location of flexplanes 712 (e.g., flexplane 712a, flexplane 712b) implemented in a data system rack 702 can vary. A modular optical horizontal flexplane 712a can be located extending horizontally near the bottom of an enclosure 704 connecting to nodes at ports (e.g., port 706) in the enclosure 704, as shown in FIG. 7. A modular optical vertical flexplane 712b can extend vertically connected to a rack 702 via horizontally extending flexplanes (e.g., flexplane 712a) and to extension points (e.g., extension point 710). The extension points 710 connect a vertical flexplane 712b to another vertical flexplane 712b. In some implementations, a vertical flexplane 712b can optically interconnect devices located within at least two enclosures 704 located at different vertical levels. In some implementations, a horizontal flexplane 712a can optically interconnect devices located within one enclosure 704. In some implementations, a vertical flexplane 712b can optically interconnect with at least one horizontal flexplane 712a. Various configurations of the vertical and horizontal flexplanes 712 can be implemented to provide the intra- and inter-dimensionally scalable torus technology. Such various configurations also provide access to nodes that are located in numerous locations throughout the rack and may not be conveniently reached for connections (e.g., nodes located away from the edges of the enclosures).

Referring to FIG. 7, 343 modular optical flexplanes 712 are located extending horizontally near the bottom of the seven enclosures 704 in each of 49 racks connecting to nodes at ports 706 in the enclosures 704. 343 modular optical flexplanes 712 are located extending vertically connected to the rack 702 via the flexplanes 712 extending horizontally and to extension points 710. An exploded view shows the torus topology 708 in this implementation. Seven 3D (7×4×7) tori are connected together to form a 4D (7×4×7×7) torus. In this implementation, the links between the bottom left hand node from 3D volume to 3D volume is shown. This implementation can also be extended to form a 5D torus, such as 7×4×7×7×N, where N can be any number of nodes in the 5th dimension.

The above specification, examples, and data provide a complete description of the structure and use of exemplary embodiments of the invention. Since many embodiments of the invention can be made without departing from the spirit and scope of the invention, the invention resides in the claims hereinafter appended. Furthermore, structural features of the different embodiments may be combined in yet another embodiment without departing from the recited claims.

What is claimed is:

1. A system comprising:
a data center rack including one or more enclosures, each of the enclosures including one or more devices; and
a plurality of flexplane units configured to interconnect with each other so as to interconnect a plurality of nodes in an nD torus topology, the one or more of the plurality of nodes connected to one or more of the devices.

2. The system of claim 1, wherein each of the plurality of flexplane units are modular interconnectable optical flexplanes.

3. The system of claim 1, wherein at least one flexplane unit is a vertical flexplane unit optically interconnecting devices located within at least two enclosures located at different vertical levels.

4. The system of claim 1, wherein at least one flexplane unit is a horizontal flexplane unit optically interconnecting devices located within an enclosure.

5. The system of claim 1, wherein at least one vertical flexplane unit is interconnected with at least one horizontal flexplane unit.

6. The system of claim 6, wherein each node supports up to 32 bidirectional ports.

7. The system of claim 1, wherein the one or more devices are at least one of end devices, servers, microservers, data storage devices, switches, and computers.

8. The system of claim 1, wherein the nD torus topology is at least three dimensions.

9. An apparatus comprising:
an interconnectable optical flexplane assembly configured to connect one or more of a plurality of devices of a data center rack in a torus topology.

10. The apparatus of claim 9, wherein the interconnectable optical flexplane assembly is formed of a plurality of modular flexplane units.

11. The apparatus of claim 10, wherein at least one flexplane unit is a vertical flexplane unit optically interconnecting at least two of the plurality of devices located within two enclosures located at different vertical levels.

12. The apparatus of claim 10, wherein at least one flexplane unit is a horizontal flexplane unit optically interconnecting at least two of the plurality of devices located within an enclosure.

13. The apparatus of claim 10, wherein the interconnectable optical flexplane assembly includes at least one vertical flexplane unit interconnected with at least one horizontal flexplane unit.

14. The apparatus of claim 9, wherein the interconnectable optical flexplane assembly is configured connect to the plurality of devices via nodes located on the data center rack.

15. The apparatus of claim 9, wherein the torus topology is at least three dimensions.

16. A storage system, comprising:
a data center rack;
at least one storage enclosure configured in the data center rack, the at least one storage enclosure including a plurality of devices interconnected with each other in a torus topology; and
an interconnectable optical flexplane configured to connect one or more of the plurality of devices.

17. The storage system of claim 16, wherein the interconnectable optical flexplane is configured to connect to the one or more of the plurality of devices via nodes in the data center rack.

18. The storage system of claim 16, wherein the torus topology is at least three dimensions.

19. The storage system of claim 16, wherein at least one interconnectable optical flexplane unit is a vertical flexplane unit optically interconnecting devices located within at least two enclosures located at different vertical levels.

20. The storage system of claim 15, wherein at least one interconnectable optical flexplane unit is a horizontal flexplane unit optically interconnecting devices located within an enclosure.
